(19) United States
(12) Patent Application Publication
(10) Pub. No.: US 2016/0313415 A1
(43) Pub. Date: Oct. 27, 2016

(54) MEASURING HEAD, MEASURING SYSTEM AND METHOD FOR DETERMINING A QUALITY OF A MAGNETIC BLOCK FOR AN ENERGY CONVERTER

(71) Applicant: ZF FRIEDRICHSHAFEN AG, Friedrichshafen (DE)

(72) Inventor: Eduard Ruff, Auerbach (DE)

(73) Assignee: ZF Friedrichshafen AG, Friedrichshafen (DE)

(21) Appl. No.: 15/102,476

(22) PCT Filed: Nov. 11, 2014
(86) PCT No.: PCT/EP2014/074217

§ 371 Date: Jun. 7, 2016

(30) Foreign Application Priority Data
Dec. 11, 2013 (DE) 102013225580.2

(51) Int. Cl. G01R 33/12; G01R 33/07

(52) U.S. Cl. CPC G01R 33/1215; G01R 33/072

(57) ABSTRACT

The present disclosure provides a measuring head for detecting a magnetic field provided by a magnet block having three pole surfaces. The measuring head may have three magnetic conductors for conducting the magnetic field. Each magnetic conductor may include an end face, where in at least one arrangement of the three magnetic conductors, the three end faces are arranged in one plane corresponding to the arrangement of the three pole surfaces. The measuring head may also include two sensors configured to detect the magnetic field.

The present disclosure relates to a measuring head for detecting a magnetic field which is provided by a magnet block for an energy converter, a corresponding measuring system that uses the measuring head, a method for determining a quality of a magnet block for a power converter as well as a corresponding computer program product.

Energy converters, also referred to as energy harvesters, are used in more and more applications. In order to ensure a proper operation of such power converters, it is necessary to check or monitor their geometric and magnetic properties as well as material properties.

The disclosure document DE 10 2010 003 151 A1 describes an induction generator for a radio switch with a magnetic element and an induction coil with a coil core.

The DE 10 2011 07 8932 A1 discloses an induction generator for a radio switch comprising a magnetic element having a north pole contact segment and a south pole contact segment as well as a coil core which consists of pole contact segments for connecting to the north pole contact segment and the south pole contact segment.

In view of the above, the present disclosure provides an improved measuring head for detecting a magnetic field which is provided by a magnet block for an energy converter, a measuring system for determining a quality of a magnet block for an energy converter, a corresponding method for determining a quality of a magnet block for an energy converter as well as a corresponding computer program product with a program code to execute the method. Advantageous embodiments can be derived from the following description.

By means of a measuring device or procedure it is possible to perform a measurement of magnetic and geometric properties of a magnetic system, or of a magnetic composite with magnet conductor pieces during the production. The magnet system or the magnet composite may hereby be referred to as a magnetic head. By detecting and evaluating the magnetic field that is caused by a magnetic system, it is possible to draw conclusions regarding the geometrical properties. It is therefore possible to define a tolerance for the magnetic field, which is in accordance to the corresponding geometric tolerances. The magnetic field can be tapped at defined positions and supplied to respective sensors via magnet conductors.

A measuring head for detecting a magnetic field which is provided by a magnet block for an energy converter, whereby the magnet block consist of three pole surfaces that are arranged in one plane in order to provide the magnetic field, comprises:

three magnetic conductors to conduct the magnetic field, whereby one arrangement of the three magnetic conductors where the end faces are arranged in one plane corresponds to one reference arrangement of the three pole surfaces; and

two sensors to detect the magnetic field.

The magnet block may be part of one induction generator or of one energy converter for a radio switch. This may be an energy converter as it is described in the disclosure documents DE 102010003151 A1 and DE 102011078932 A1. The magnet block can be a magnet system with a backiron. The magnet block may consist of at least one magnet and two conductor pieces that are formed as pole pieces, whereby the one conductor piece may be designed with two of the pole surfaces and the other conductor piece with the other pole surface. The magnet block can be a magnetic element with at least one north pole contact segment and at least one south pole contact segment, whereby two of the pole surfaces are assigned either to the north pole contact segment or to the south pole contact segment and the remaining pole surface is assigned to the other pole contact segment. It is thus possible that the three pole surfaces have at least two different polarities. The two pole surfaces with the greatest distance can have the same polarity. When the end faces of the three magnet conductors are arranged to the pole surfaces of the magnet block, then the magnetic field, which is provided by the magnet block, can be directed through the magnet conductors.

The three magnet conductors may include a first side magnet conductor, a middle magnet conductor and a second side magnet conductor. The three magnet conductors may hereby be arranged parallel to each other. The three magnet conductors can be arranged at a distance towards each other. The three magnet conductors may feature an essentially rectangular form. The respective end faces may hereby be arranged in the direction of the main extension direction of the magnet conductor. Without the two sensors, a gap may occur between the magnet conductors.

The two sensors can be designed as Hall sensors. A Hall sensor or Hall effect sensor can also be described as a Hall probe or Hall generator. The two sensors can use the Hall effect to measure magnetic fields.

It is also practical, if a first sensor of the two sensors is arranged between the first side magnet conductor and the middle magnet conductor. It is furthermore practical if a second sensor of the two sensors is arranged between the middle magnet conductor and the second side magnet conductor. Thus, two magnet conductors can be positioned directly on one sensor. It is thus impossible that an air gap can form between sensor and magnetic field. The sensors can therefore be arranged at one longitudinal side of the magnet conductor. The middle magnet conductor can be bordered by two sensors. Advantageously, due to the arrangement of the sensors it is possible to precisely detect the magnetic field that is directed through the magnet conductors.

The three magnet conductors can be held in a non-magnetic mounting fixture. The non-magnetic mounting fixture can be made of e.g. non-ferrous metal, plastic or ceramic. It is thus possible to create a form-stable unit.

One side surface of the measuring head can be designed as an even reference measuring plane. An even reference measuring plane may particularly be created by means of a sanding and additionally or alternatively by means of a polishing of the side surface. The reference measuring plane can stretch within a tolerance range of a plane. The side surface of the arrangement of the end faces of the three magnet conductors that are arranged in one plane may hereby correspond to a reference arrangement of the three pole surfaces. If a magnet block is manufactured within the tolerance range, it is thus possible to pick up the magnetic field from the magnet conductors and to detect it by means of the sensors.

A measuring system to determine a quality of a magnet block of an energy converter includes:

a measuring head according to one of the previously described embodiments; and

a data evaluation system, which is connected to the two sensors of the measuring head, whereby the data evaluation system is designed to record a first sensor signal of the first sensor that is representing the magnetic field of the magnet block and a second sensor signal of the second sensor that is representing the magnetic field of the magnet block and to additionally or alternatively evaluate it, in order to determine a quality of the magnet block.

The quality can be determined by monitoring a magnetic field emanating from the magnet block. The magnet block may consist of at least one magnet and two conductor pieces that are formed as pole pieces, whereby three pole surfaces are formed on one side of the magnet block. The magnet block can preferably be designed as it was described before.

A data evaluation system can be an electrical device, which processes sensor signals and issues control signals in dependence on these. The data evaluation system can consist of one or more suitable interface/s, which can be designed as hardware and/or software. When designed as hardware, the interfaces can be e.g. part of an integrated circuit in which functions of the data evaluation system are implemented. But, the interfaces can also be separate, integrated circuits, or at least partially be composed of discrete components. When designed as software, the interfaces may be software modules which are available e.g. on a micro-controller in addition to other software modules.

The measuring head can be arranged in a positioning device. The positioning device can hereby feature at least one guide rail, in particular two guide rails. A base plane of the positioning device can feature three recesses, in which the magnet conductors are arranged in such a way that the end faces of the magnet conductors are situated in an even way within this base plane.

The measuring system can include a means for transporting. The means for transporting can be designed to transport the magnet block to the measuring system. The magnet block can hereby be moved over the end faces of the magnet conductors. The means for transporting can be designed to align the pole surfaces of the magnet block to the end faces of the magnet conductors or to move the pole surfaces over these. Advantageously, the means for transporting and the positioning device can work together.

A method for determining a quality of a magnet block for an energy converter is presented. A magnetic field can hereby emanate from the magnet block. The magnet block can consist of three pole surfaces that are arranged in one plane on one side of the arrangement in order to provide the magnetic field. The method involves the following steps:

conducting of the magnetic field through three magnet conductors;

detecting of the magnetic field by using two sensors and providing of a first sensor signal and a second sensor signal, whereby the first sensor signal represents a force of the magnetic field at a sensor position of a first sensor of the two sensors and the second sensor signal represents a force of the magnetic field at a sensor position of a second sensor of the two sensors; and

evaluating of the first sensor signal and of the second sensor signal to determine a quality of the magnet block.

The underlying idea of the disclosure can also be implemented efficiently and economically by means of the method to determine a quality of a magnet block of an energy converter.

In the step of evaluating, the first sensor signal and the second sensor signal can be combined in order to generate a result signal representing the quality of magnet block. The first sensor signal and the second sensor signal can hereby be combined by means of addition in order to generate the result signal. A difference between the amount of the first sensor signal and the amount of the second sensor signal can be calculated in order to generate the results signal. Alternatively, the second sensor signal can be subtracted from the first sensor signal in order to generate the result signal.

The step of evaluating can include a step of comparing. In the step of comparing the results signal can be compared at least to a predetermined threshold in order to determine the quality of the magnet block. Alternatively, the result signal can be compared to two thresholds in order to verify whether the result signal is within a tolerance range, to determine the quality of the magnet block.

Such an approach can be used, for example, as a replacement or complement to other methods and procedures for the dimension measurement of an object or component, which use e.g. measuring microscopes, cameras, or tactile measuring equipment. It is hereby possible to fall back to methods and procedures for the measurement of a magnetic field, such as e.g. measurements on the basis of Hall sensors, or corresponding scan procedures. The described approach can also be used, for example in the context of methods for the determination of the material or of material properties.

In a quick manner, during series production and without any damage to the parts, it can be checked whether the right materials were used or a quality state of pole pieces or of a magnet can be assessed, a correct polarity or orientation of the magnet (North-South) can be checked. Magnetic properties of the magnet and the pole pieces (process fluctuations) can advantageously be tested. Thermal damage during an injection molding process can be discovered. Thus, a dimensional accuracy of the metal components and/or plastic component particularly in the area of the pole surfaces can be assessed, as well as flatness, symmetrical deviation, surface defects, ridges and overmolding. The advantage hereby is that such an examination can be performed quickly and in an economically feasible way and an integration in the production line is guaranteed.

Another advantage is a computer program product with a program code that can be stored on a machine-readable carrier such as a semiconductor memory, a hard drive or an optical storage and which can be used to execute the method according to one of the embodiments that were described earlier when the program is run on a computer, a device or a data evaluation system.

Advantageously it is possible to check and/or to monitor the quality, the dimensional accuracy and the compliance with the magnetic properties by means of an embodiment of the presented in the manufacturing process of a magnet block or of a magnetic system with backiron, such as are used e.g. for a self-sustaining energy converter.

The current embodiments are explained in more detail by means of the examples in the enclosed drawings. It is shown:

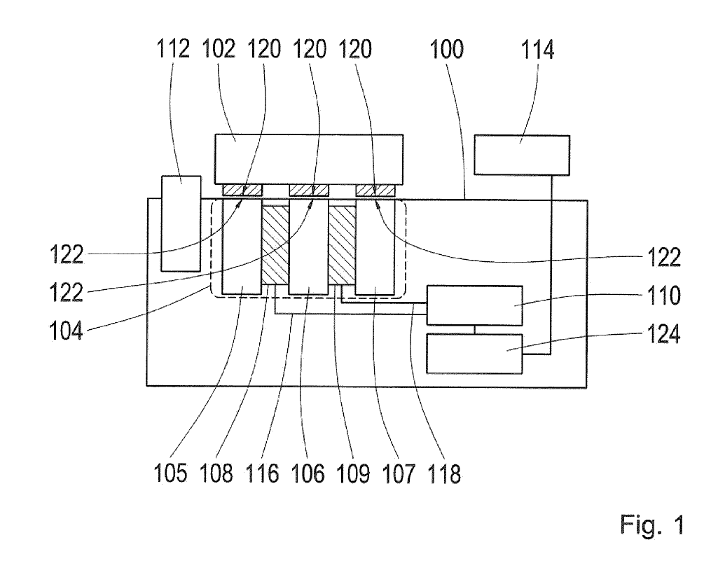

FIG. 1 a block diagram of a measuring system to determine a quality of a magnet block of an energy converter according to an embodiment of the present disclosure;

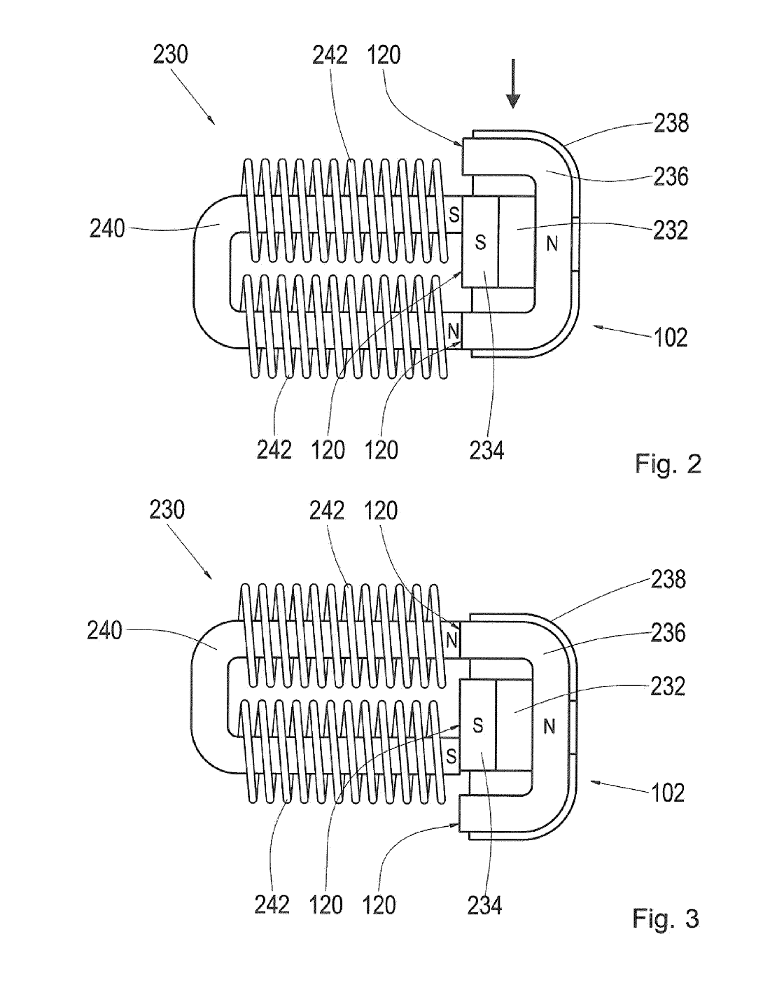

FIG. 2 a depiction of an energy converter with a magnet block according to an embodiment of the present disclosure;

FIG. 3 a depiction of an energy converter with a magnet block according to an embodiment of the present disclosure;

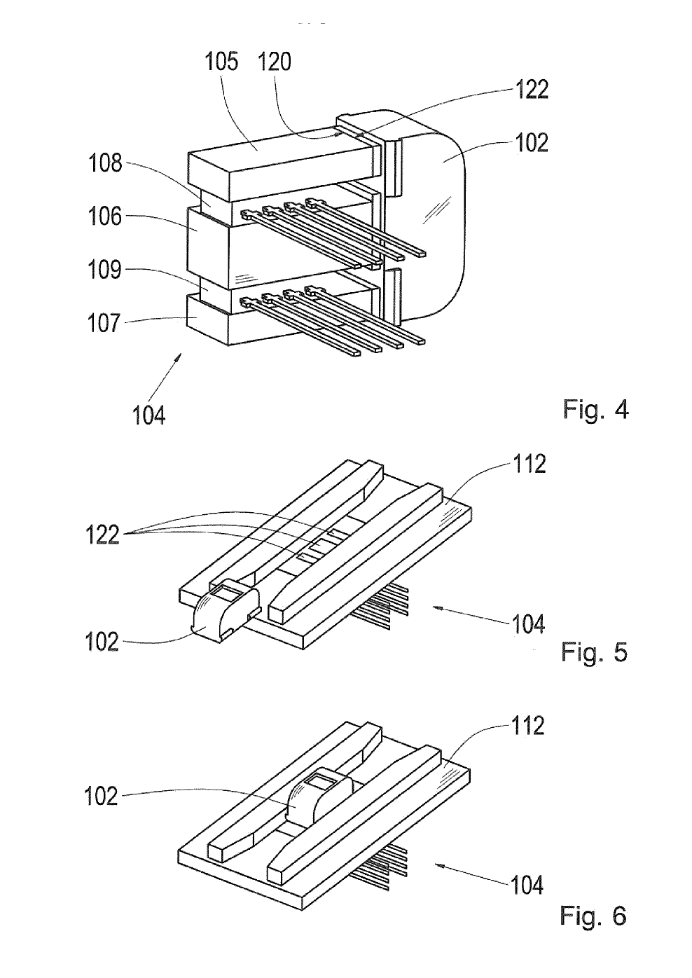

FIG. 4 a depiction of a measuring head to detect a magnetic field that is provided by a magnet block of an energy converter according to an embodiment of the present disclosure;

FIG. 5 a simplified depiction of a measuring system to determine a quality of a magnet block of an energy converter according to an embodiment of the present disclosure;

FIG. 6 a schematic depiction of a measuring system to determine a quality of a magnet block of an energy converter according to an embodiment of the present disclosure;

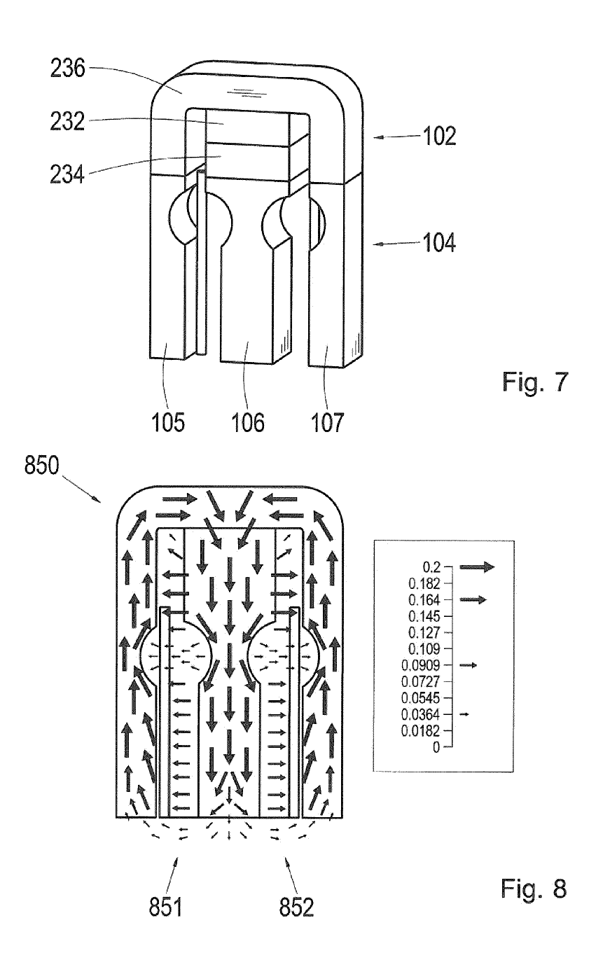

FIG. 7 a depiction of a measuring head and of a magnet block according to an embodiment of the present disclosure;

FIG. 8 a simplified depiction of a magnetic field in a measuring head that is arranged on a magnet block according to an embodiment of the present disclosure;

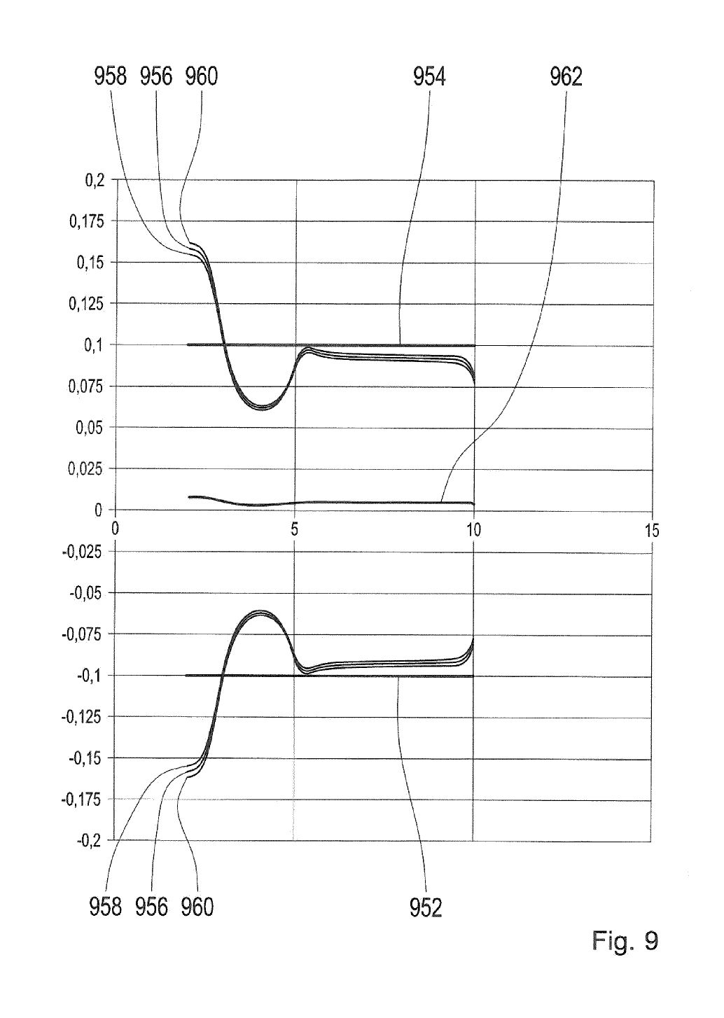

FIG. 9 a graphical depiction of a flux density in a magnetic field according to an embodiment of the present disclosure;

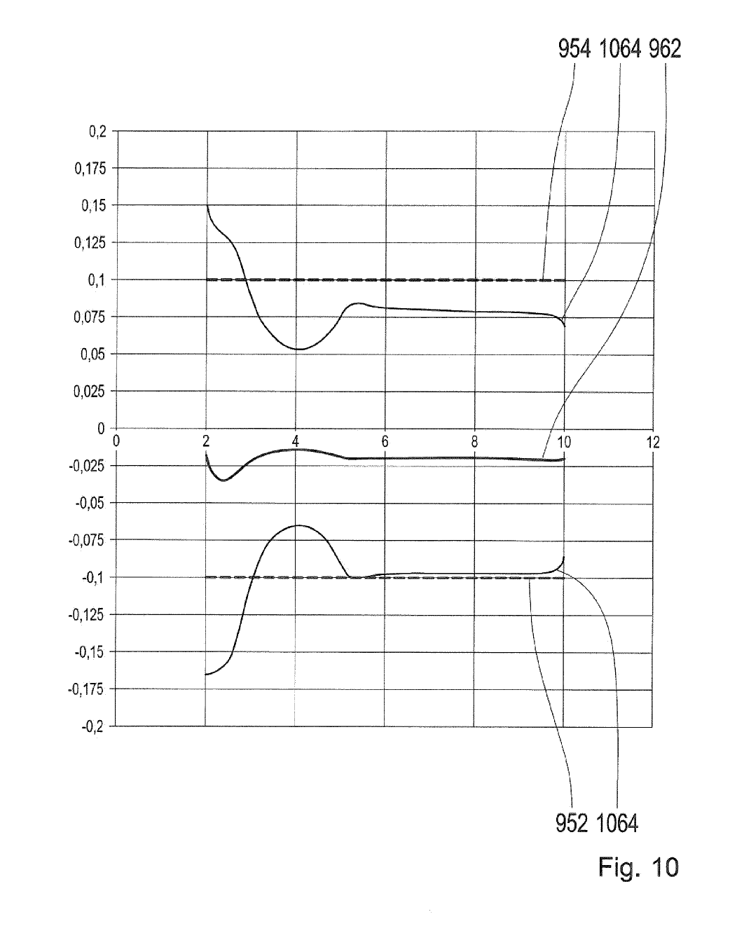

FIG. 10 a graphical depiction of a flux density in a magnetic field according to an embodiment of the present disclosure;

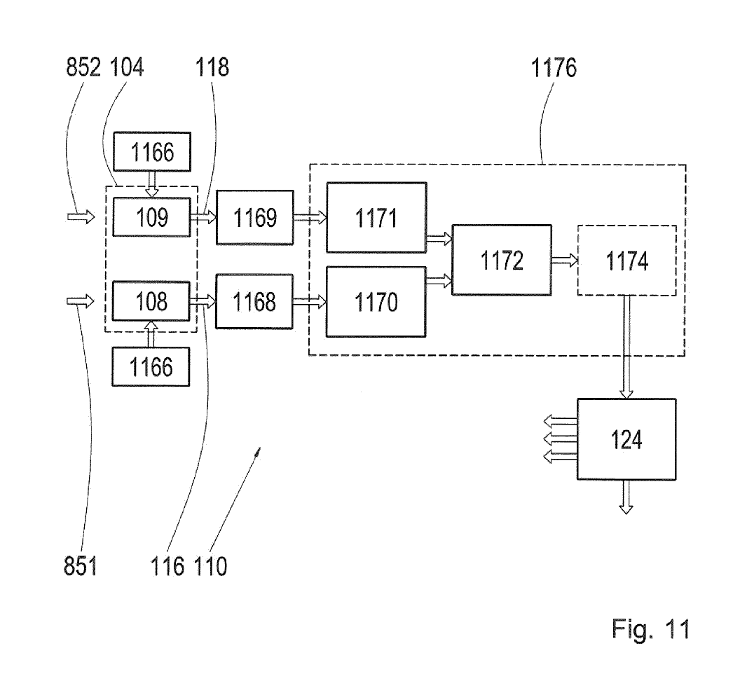

FIG. 11 a block diagram of a data evaluation system to determine a quality of a magnet block of an energy converter according to an embodiment of the present disclosure; and

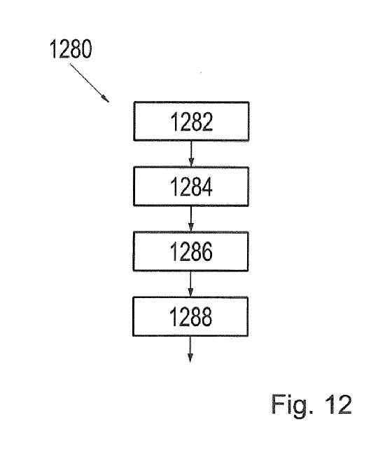

FIG. 12 a flow chart of a method to determine a quality of a magnet block of an energy converter according to an embodiment of the present disclosure.

In the following description of preferred embodiments of the present disclosure, same or similar reference signs are used for the elements that are depicted and that function in a similar way in the various figures, whereby a repeated description of these elements is omitted.

FIG. 1 depicts a block diagram of a measuring system 100 to determine a quality of a magnet block 102 of an energy converter according to an embodiment of the present disclosure.

The measuring system 100 features a measuring head 104 with three magnet conductors 105, 106, 107 and two sensors 108, 109 and a data evaluation system 110. In the shown embodiment, measuring system 100 further includes an optional positioning device 112 as well as an optional means for transporting 114. The two sensors 108, 109 are connected to the data evaluation system 110. The first sensor 108 provides a first sensor signal 116 of the data evaluation system 110. The second sensor 109 provides a second sensor signal 118 of the data evaluation system 110.

The magnet block 102 consists of three pole surfaces 120. A more detailed description of an embodiment of the magnet block 102 will follow in FIG. 2 and FIG. 3. One of the three respective pole surfaces 120 is situated at one respective end face 122 of each of the three magnet conductors 105, 106, 107. The arrangement of the end faces 122 of the three magnet conductors 105, 106, 107 that are arranged in one plane corresponds to a reference arrangement of the three pole surfaces 120.

The measuring system 100 furthermore consists of an optional control unit 124. The control unit 124 is connected via control lines to the data evaluation system 110 and to the means for transporting 114. The control unit 124 is designed to provide appropriate control signals for the means for transporting 114 in order to move the magnet block 102 into a measuring position. The means for transporting 114 is designed to transport the magnet block 102 to the measuring system 100. By means of appropriate control signals and a corresponding action of the means for transporting 114 after a measurement, it is furthermore possible to perform a sorting operation or also a dividing or separating of good and bad magnet blocks 102, i.e. according to the quality that was determined by the measuring system 100. In addition to that, the control unit 124 is connected to the data evaluation system 110 in order to provide appropriate control signals to start a measurement or a data analysis or to receive a corresponding signal from the data evaluation system 110 that is representing a quality. Thus the quality can be depicted as binary information for good and bad, or alternatively in a deviation from a standard size or the like.

FIG. 2 shows a depiction of an energy converter 230 with a magnet block 102 according to an embodiment of the present disclosure. The magnet block 102 of the energy converter 230 can be an embodiment of a magnet block 102 that was shown in FIG. 1. The magnet block 102 consists of a magnet 232 as well as two conductor pieces 234, 236 that are arranged in a housing. The magnet 232 has a rectangular shape. A first conductor piece 234 with its longitudinal side is positioned directly adjacent to the magnet 232 and forms a south pole contact segment, whereby a side surface of the first conductor piece 234, which is situated opposite of magnet 232, represents a pole face 120 of the magnet block 102. The second conductor piece 236 is positioned directly adjacent to the side of magnet 232 which lies opposite of the first conductor piece 234 and forms a north pole contact segment. The second conductor piece 236 features a U-shape. When viewed in a different way, the second conductor piece 236 features a C-shape. The second conductor piece 236 hereby contacts magnet 232 on the inside of the U with the lower crosspiece of the U. The two ends of the U form one respective pole surface 120 each. The magnet block 232 as well as the two conductor pieces 234, 236 are arranged in a housing 238. The energy converter 230 furthermore consists of a magnetic core 240, which features a U-shape where one respective coil 242 is arranged around its two arms. An arrow indicates a possible direction of movement of the magnet block 102 relative to the magnetic core 240, whereby the energy converter 230 is depicted and described after the movement of the magnet block 102 in FIG. 3 according to direction of the movement as it is depicted by the arrow.

The magnet block 102 of an energy converter 230 consists of a magnet 232 and of two conductor pieces 234, 236 (pole pieces 234, 236) molded with a plastic fitting 238. The conductor pieces 234, 236 are designed in such a way that three pole surfaces 120 are arranged on the moveable side of the magnet block 102.

In each case, two of three pole surfaces 120 of the magnet block 102 are magnetically coupled with the pole surfaces of magnetic core 240 by means of a mechanical support plate in an alternating way. When the energy converter 230 is activated, the pole surfaces of magnetic core 240 are commutated with the other two pole surfaces 120 of the magnet block 102 (with support plate). The result within the magnetic core 240 is a sudden change of the magnetic flux and induction of electrical energy in the coil 242 of the energy converter 230. When switching backwards, the reverse process is created. The polarity of the voltage pulse changes hereby and is used for a detection of a direction in the radio switch.

It is enormously important that the pole surfaces 120 of the magnet block 102 and the pole surface of the magnetic core 240 are formed without any geometric error, that the contact surfaces of both positions must fully rest on the complete area, that the materials must have defined magnetic properties and that the magnets 232 feature a defined magnetic orientation.

It is possible to detect geometric errors with an inspection by a camera, but this would be accomplished with a high measuring inaccuracy. The flatness errors, damages on the surface and a possible ridge can only be detected by means of very complex measuring procedures.

Even more problematic for the prior art would be the measuring of the flux density at the pole surfaces 120, i.e. of an interface layer to the magnetic core 240. It is crucial for the function of the energy converter 230, which flux density is induced into the magnetic core 240, since the smallest gap of e.g. 0.05 mm will significantly weaken the flux density in the magnetic core 240.

So-called scanning procedures along a surface would be possible here. However these procedures are very expensive and cannot be integrated in a production process. Both magnetic circuits have to be tested (according to the two switching states, as they are depicted in FIG. 2 and FIG. 3), which would generally demand for two examination steps.

FIG. 3 shows a depiction of an energy converter 230 with a magnet block 102 according to an embodiment of the present disclosure. The energy converter 230 can be an embodiment of the energy converter 230 that was shown in FIG. 2. Thus, the magnet block 102 can be an embodiment of the magnet block 102 that was shown in FIG. 1 or FIG. 2. The depiction in FIG. 3 mainly corresponds to the depiction of the energy converter 230 in FIG. 2, with the difference that the magnet block 102 is displayed in a second switching state which is different from the one in FIG. 2. This can be seen in a different position of the contacting pole surface of the magnetic core 240 and the pole surfaces 120 of the magnet block 102. This leads to the polarity of the magnetic core 240 that is described in FIG. 2.

FIG. 4 shows a depiction of a measuring head 104 to detect a magnetic field that is provided by a magnet block 102 of an energy converter 230 according to an embodiment of the present disclosure. The energy converter 230 can be an embodiment of the energy converter 230 that was shown in FIG. 2 or FIG. 3. Thus, the magnet block 102 can be an embodiment of the magnet block 102 that was described in FIG. 1 to FIG. 3. The measuring head 104 can be an embodiment of the measuring head 104 that was described in FIG. 1. The measuring head 104 consists of three magnet conductors 105, 106, 107 as well as two sensors 108, 109. The two sensors 108, 109 include four respective connection cables. The sensors 108, 109 can be powered by means of two cables. Two further cables provide the corresponding sensor signal. One respective end face 122 of the magnet conductors 105, 106, 107 is aligned to one pole surface 120 of the magnet block 102. The flux of the magnetic field that is emanating from the magnetic block 102 is depicted and described in more detail in FIG. 8.

The sensors 108, 109 completely fill the space between two adjacent magnet conductors 105, 106, 107. The two sensors 108,109 in the depicted embodiment can be designed as Hall sensors. The connection cables of the sensors 108, 109 can be connected to a data evaluation system.

FIG. 5 shows a simplified depiction of a measuring system 100 to determine a quality of a magnet block 102 of an energy converter according to an embodiment of the present disclosure. The measuring system 100 can be an embodiment of a measuring system 100 that was described in FIG. 1. The energy converter can be an embodiment of an energy converter 230 that was described in FIG. 2 or FIG. 3. The measuring head 104 is combined with a positioning device 112, so that the three end faces 122 of the three magnet conductors of the measuring system 100 can be contacted within one flat surface of the positioning device 112. The positioning device 112 furthermore has two positioning rails that serve as a limit stop for the magnet block 102. In FIG. 5, the magnet block 102 is brought to the positioning device 112. In FIG. 6, the magnet block 102 is depicted in a position to execute the method that is described in FIG. 12.

The measuring system 100 essentially consists of a measuring head 104 and of the electronic data evaluation system as it is described in FIG. 1 or later on in more detail in FIG. 11.

Measuring head 104 comprises three magnet conductors 105, 106, 107, which are mounted in a non-magnetic mounting fixture. The non-magnetic mounting fixture can be made of e.g. non-ferrous metal, plastic or ceramic. The surface to the test object is finely sanded or polished, and thus forms a plane reference measuring surface. Two Hall sensors are situated between the three magnet conductors 105, 106, 107, which can detect the magnetic field strength between the conductor pieces or the magnet conductors.

During the examination, magnet block 102 is brought into a measuring position by means of transporting and centering. Magnetic pull ensures that magnet block 102 is pressed onto measuring head 104 with a defined force.

In the measuring position, the magnetic field lines are no longer shorted through the air, but they now run through the magnet conductors of the measuring head 104. To a large extent, the magnetic field is hereby evenly distributed between the middle magnet conductor and the two magnet conductors on the sides. The two Hall sensors are located in two gaps and are designed to detect the magnetic fields.

In one embodiment, the sensors (Hall sensors) are supplied with a constant voltage. A respective voltmeter is connected to the output terminals of the two sensors. Appropriate logic modules of the data evaluation system, for example designed as a PC measuring station, are designed to record the measured voltages, to set these in relation to each other and to compare them with permissible limits and to trigger an appropriate partial manipulation. A partial manipulation can be, e.g. a sorting out of an unsuitable component, an output of a log file or a releasing of a suitable component. The underlying waveforms of the signals are depicted and described in FIG. 9 and FIG. 10.

The magnetic field strength is advantageously adapted to the sensitivity of the programmable Hall sensors. The adaption can be adjusted by the size of the gap (sensor area), or by the surface area of the magnet conductor.

FIG. 6 shows a schematic depiction of a measuring system 100 to determine a quality of a magnet block 102 of an energy converter 230 according to an embodiment of the present disclosure. The measuring system 100 can be an embodiment of the measuring system 100 that was described in FIG. 5. In contrast to FIG. 5, magnet block 102 is positioned in such a way that one respective pole surface of the three pole surfaces of the magnet block 102 contacts one respective end face of the three magnet conductors. The quality examination of magnet block 102 can be performed in this position.

FIG. 7 shows a depiction of a measuring head 104 and of a magnet block 102 according to an embodiment of the present disclosure. Both, the magnet block 102 as well as the measuring head 104 can be embodiments of a magnet block 102 or a measuring head 104 that were shown in FIG. 1 or FIG. 4 to FIG. 6. The magnet block 102 consists of a magnet 232 as well as two conductor pieces 234, 236. The measuring head 104 consists of three magnet conductors 105, 106, 107. The magnet conductors 105, 106, 107 feature an essentially rectangular form. On a longitudinal side, the magnet conductors 105, 106, 107 feature a semi-circular recess on a side that is facing a neighboring magnet conductor 105, 106, 107, so that is a respectively circular recess is produced by the air gap between the two magnet conductors 105, 106, 107 and the two recesses of the magnet conductors 105, 106, 107 that are facing each other. The measuring head 104 is contacting magnet block 102 via three end faces of the magnet conductors 105, 106, 107. In particular, three pole surfaces of the magnet block 102 are in contact with the end faces of the magnet conductors 105, 106, 107. The embodiment that is depicted here serves as basis for the magnetic field 850 that is shown in FIG. 8.

FIG. 8 shows a simplified depiction of a magnetic field 850 in a measuring head that is arranged on a magnet block according to an embodiment of the present disclosure. The magnet block 102 and the measuring head 104 can be an embodiment of the magnet block 102 and of the measuring head 104 that is shown in FIG. 7. Arrows show the course of the magnetic field 850, starting from the magnet 232 in FIG. 7, via the conductor pieces 234, 236 as well as the magnet conductors 105, 106, 107. The magnetic field 850 can be detected e.g. by the sensors 108, 109 that are depicted in FIG. 4, and can be made available as a sensor signal which represents the magnetic field 850. Hereby a first magnetic field 851 operates between the first outer magnet conductor 105 and the middle magnet conductor 106 as they are depicted in FIG. 7, and a second magnetic field 852 operates between the second outer magnet conductor 107 and the middle magnet conductor 106.

For example, the magnetic fields 851, 852 in the embodiment that is depicted in FIG. 4 have an effect on the sensors 108, 109. The sensors in FIG. 4 or in FIG. 11 each provide a sensor signal that is representing the respective magnetic field 851, 852.

The programmable Hall sensors are balanced out or programmed by means of reference components before startup, so that the same output voltage is brought forth from both Hall sensors by means of the idealized components.

FIG. 9 shows a graphical depiction of a flux density in a magnetic field according to an embodiment of the present disclosure. In a Cartesian coordinate system a measurement course in millimeters [mm] is shown on the horizontal axis and a flux density in Tesla [T] is shown on the vertical axis. The representation scale on the horizontal axis ranges from the origin at zero millimeters up to fifteen millimeter measuring range. On the vertical axis, a flux density is depicted in a range from −0.2 Tesla to +0.2 Tesla. The diagram representation in FIG. 9 depicts three signal waveforms for each sensor. Furthermore, a minimum limit value 952 and a maximum limit value 954 is depicted as an appropriate threshold value. The minimum limit value 952 in the depicted embodiment is set at −100 mT. The maximum limit value 954 in the depicted embodiment is set at +100 mT.

In the chart shown in FIG. 9, a pair of signal waveforms 956, 958, 960 is always to be viewed as one unit. Thus, signal waveforms 956 depict a nominal remanence of the magnet, the signal waveforms 958 depict a minimum remanence and the signal waveforms 960 a maximum remanence of the magnet. In other words, the three pairs of signal waveforms 956, 958, 960 depict a permissible tolerance for a magnet block according to a magnet block 102, as it is referred to with the reference sign 102 in the preceding figures. The signal waveform 962 depicts a difference of a related pair of signal waveforms, in this case of the signal waveform 956 with a nominal remanence of a related pair of signal waveforms.

The magnetic remanence of signal waveforms 956, 958, 960 as it is shown in FIG. 9 amounts to 1.125 T at a nominal remanence, at a minimum remanence to 1.10 T and at a maximum remanence to 1.15 T.

As long as the magnet block is symmetrical and the materials properties are as planned, the magnetic fields (reference sign 850 in FIG. 8) are distributed symmetrically in the measuring head and the Hall sensors register equally strong magnetic fields. The variations of the remanence of the magnet or of the pole pieces lead to the magnetic field in the measuring range of the sensors being strengthened or weakened. The sensors can then register the difference. Three respective curves can be seen for each sensor in FIG. 9. The curves correspond to a minimum, nominal and maximum remanence of the magnet, i.e. according to a permissible tolerance of a batch or delivery charge. By means of setting the maximum and minimum limit values, unsuitable components can be detected and selected or sorted out.

If the change of the magnetic field in the area of the sensor is even stronger, it will produce an air gap between the magnet block and the measuring head. Caused by e.g. an irregular contact surface of the magnet block, surface errors, impurities, ridges, excess molding and deformations of the pole surfaces, an air gap can appear. The air gap can also occur asymmetrically, such as when one of the three pole surfaces is shorter than the other two pole surfaces. In practice, this will lead to different energetic pulse generations when a generator is activated or switched back. This is highly undesirable. In such a case, the magnetic field is no longer distributed symmetrically in the measuring head and the Hall sensors will generate different output signals.

FIG. 10 shows a graphical depiction of a flux density in a magnetic field according to an embodiment of the present disclosure. The depiction corresponds to the type of depiction in FIG. 9. In contrast to FIG. 9, where the signal waveforms are within a tolerance range, FIG. 10 depicts a simulation of an unsuitable component, in which one of the pole surfaces of the magnet block was shortened by only 0.05 mm.

The examination is performed in one embodiment as a static examination, which means that the component or the magnet block remains in the measuring position. After the measurement, the component is transported further into a packaging. Since the measuring cycle is relatively short, an integration into the production cycle does not cause any problems. But if the measurement is to be integrated in a production facility with several cavities, one embodiment offers the possibility to realize the examination dynamically. It is hereby not necessary to stop the component in the measuring position. In such a case, the two voltmeters of the data evaluation system will be replaced by a two-channel multi-function device such as e.g. an oscilloscope with a signal resolution on the voltage and timeline.

Two pulses occur during the examination. The highest points of the curves or waveforms correspond to the measured values. If there is a variation of the grid dimension on the magnet block, e.g. by a deformation or deviation of the pole pieces, the two impulses will experience a time offset. In such a case it is possible to set a maximum permissible limit value in the timeline and to select the components where the measured value exceeded the limit as unsuitable parts.

By means of this measure, the measuring cycle can be shortened significantly, since it is no longer necessary to stop the components in the measuring position.

FIG. 11 shows a block diagram of a data evaluation system 110 to determine a quality of a magnet block of an energy converter according to an embodiment of the present disclosure. The data evaluation system 110 can be an embodiment of the data evaluation system 110 that was shown in FIG. 1. A magnetic field has an effect on a measuring head 104, which is labeled with the reference sign 850 in FIG. 8. Measuring head 104 consists of two Hall sensors 108, 109, which are supplied with energy by means of the power supply 1166. A first magnetic field 851 has an effect on the first Hall sensor 108. A second magnetic field 852 has an effect on the second Hall sensor 109. The first Hall sensor 108 provides a first sensor signal 116 and the second Hall sensor 109 provides a second sensor signal 118. The sensor signals 116, 118 represent the magnetic fields 851, 852 at a measuring position of the respective Hall sensor 108, 109.

Measuring head 104 is connected to the data evaluation system 110. This means that the first sensor signal 116 will be directed to a first A/D converter 1168 and the second sensor signal 118 will be directed to a second A/D converter 1169. The A/D converters 1168, 1169 form an input interface for the data evaluation system 110. The digitized sensor signals are directed to a device 1170, 1171 for a limit value comparison, i.e. the recorded voltage is checked if it is within the range of a lower and an upper threshold. Thus, the digitized sensor signal from the first A/D converter 1168 is directed to a first device 1170 for a limit value comparison. The digitized sensor signal from the second A/D converter 1169 is directed to a second device 1171 for a limit value comparison. The first device 1170 for a limit value comparison and the second device 1171 for a limit value comparison are connected to a device 1172 for a difference value comparison, where the difference from the two digitized sensor signals is formed and where the result is checked whether it is within a tolerance range. An optional device 1174 for a dynamic examination is depicted, a comparison of a reference value based on a measurement time or Δt. A/D converter 1168, device 1170 for a limit value comparison, device 1172 for a difference value comparison as well as the optional device 1174 for a dynamic examination are altogether referred to as logic module 1176.

In one embodiment, A/D converters 1168, 1169 are designed as a voltmeter or oscilloscope to record a voltage or to detect a voltage change within a time change.

The data evaluation system 110 is designed to record and evaluate the first sensor signal 116 of the first sensor 108 which represents the magnetic field 850 of the magnet block and the second sensor signal 118 of the second sensor 109 which represents the magnetic field 850 of the magnet block, in order to determine a quality of the magnet block.

The logic module is connected to a control unit 124 or to a signal amplifier 124. The control unit 124 is designed to provide a protocol output, i.e. a protocol that can be saved and that can additionally or alternatively be printed. Furthermore, the control unit 124 is connected to control elements of an examination unit such as light barriers, a conveyor system for components, a box for unsuitable components or a marking for suitable components, or it is designed to provide corresponding control signals.

FIG. 12 shows a flow chart of a method 1280 to determine a quality of a magnet block of an energy converter according to an embodiment of the present disclosure. The magnet block can be an embodiment of a magnet block 102 that was described in the previous figures. Hereby a magnetic field emanates from the magnet block, whereby the magnet block consist of an arrangement of three pole surfaces that are arranged in one plane on one side of the magnet block in order to provide the magnetic field. Method 1280 includes a step 1282 of conducting of the magnetic field through three magnet conductors, a step 1284 of detecting the magnetic field by using two sensors and of providing of a first sensor signal and a second sensor signal, whereby the first sensor signal represents a force of the magnetic field at a sensor position of a first sensor of the two sensors and the second sensor signal represents a force of the magnetic field at a sensor position of a second sensor of the two sensors, as well as a step of evaluating 1286 of the first sensor signal and of the second sensor signal in order to determine a quality of the magnet block.

In the step of evaluating in one embodiment, the first sensor signal and the second sensor signal are combined in order to generate a result signal representing the quality of magnet block.

In an optional step 1288 of comparing, the result signal is compared at least to a predetermined threshold in order to determine the quality of the magnet block.

The embodiments described and shown in the figures are chosen only by way of example. Different embodiments may be combined in whole or with reference to individual characteristics. It is also possible that one embodiment can be supplemented by characteristics of another embodiment. Furthermore it is possible that process steps according to the disclosure can be repeated and executed in a sequence other than the one described.

If one embodiment includes an “and/or” linkage between a first characteristic and a second characteristic, this can be understood in such a way that the embodiment according to one design example features both the first characteristic and the second characteristic and according to a further embodiment that it either only features the first characteristic or only the second characteristic.

### REFERENCE SIGNS

### Reference Signs

100 Measuring system

102 Magnet block

104 Measuring head

105 First magnet conductor

106 Second magnet conductor

107 Third magnet conductor

108 First sensor

109 Second sensor

110 Data evaluation system

112 Positioning device

114 Means for transporting

116 First sensor signal

118 Second sensor signal

120 Pole surface

122 End face

124 Control unit

230 Energy converter

232 Magnet

234 Conductor piece

236 Conductor piece

238 Housing

240 Magnetic core

242 Coil

850 Magnetic field

851 First magnetic field

852 Second magnetic field

952 Minimum limit value

954 Maximum limit value

956 Pair of signal waveforms with nominal remanence

958 Pair of signal waveforms with minimum remanence

960 Pair of signal waveforms with maximum remanence

962 Difference signal

1064 Signal waveform for an unsuitable component

1166 Power supply

1168 A/D converter, analog-digital converter

1169 A/D converter, analog-digital converter

1170 Device for limit value comparison

1171 Device for limit value comparison

1172 Device for difference value comparison

1174 Optional device for a dynamic examination

1176 Logic module

1280 Method

1282 Step of conducting

1284 Step of detecting

1286 Step of evaluation

1288 Step of comparing

1-20. (canceled)

21. A measuring head for detecting a magnetic field provided by a magnet block having three pole surfaces, the measuring head comprising:
three magnetic conductors for conducting the magnetic field, each magnetic conductor including an end face, where the three magnetic conductors are arranged such that the end faces are arranged in one plane corresponding to the arrangement of the three pole surfaces; and
two sensors configured to detect the magnetic field.

22. The measuring head of claim 21, wherein the three magnetic conductors are parallel and spaced apart and include a first side magnet conductor, a middle magnet conductor, and a second side magnet conductor.

23. The measuring head of claim 22, wherein a first sensor of the two sensors is arranged between the first side magnet conductor and the middle magnet conductor, and a second sensor of the two sensors is arranged between the middle magnet conductor and the second side magnet conductor.

24. The measuring head of claim 21, wherein the two sensors are designed as Hall sensors.

25. The measuring head of claim 21, wherein the three magnet conductors are held in a non-magnetic mounting fixture.

26. The measuring head of claim 21, wherein a side surface of the measuring head comprises a measuring plane formed by sanding and/or polishing the side surface.

27. A measuring system for determining a quality of a magnet block having at least one magnet and two conductor pieces, the measuring system comprising:
a measuring head comprising:
three magnetic conductors for conducting a magnetic field provided by the magnetic block, each magnetic conductor including an end face, wherein in at least one arrangement of the three magnetic conductors, the end faces are arranged in one plane corresponding to a reference arrangement of three pole surfaces of the magnetic block; and
a first sensor and a second sensor configured to detect the magnetic field; and
a data evaluation system connected to the first sensor and the second sensor of the measuring head, wherein the data evaluation system is configured to record and/or evaluate a first sensor signal of the first sensor and a second sensor signal of the second sensor to determine a quality of the magnet block.

28. The measuring system of claim 27, wherein the measuring head includes a positioning device configured to position the magnetic block with respect to the measuring head.

29. The measuring system of claim 27, wherein the measuring system includes a transporting device configured to transport the magnet block to the measuring system.

30. The measuring system of claim 27, wherein the three magnetic conductors of the measuring head are parallel and spaced apart and include a first side magnet conductor, a middle magnet conductor, and a second side magnet conductor.

31. The measuring system of claim 30, wherein the first sensor is arranged between the first side magnet conductor and the middle magnet conductor, and wherein the second sensor is arranged between the middle magnet conductor and the second side magnet conductor.

32. The measuring system of claim 27, wherein at least one of the first sensor and the second sensor is designed as a Hall sensor.

33. The measuring system of claim 27, wherein the three magnet conductors of the measuring head are held in a non-magnetic mounting fixture.

34. The measuring system of claim 27, wherein a side surface of the measuring head comprises a measuring plane formed by sanding and/or polishing the side surface.

35. A method to determine a quality of a magnet block with three pole surfaces arranged in one plane, the method comprising:
conducting a magnetic field provided by the magnetic block through three magnet conductors;
detecting the magnetic field by using a first sensor and a second sensor, and providing a first sensor signal representing a force of the magnetic field at a sensor position of the first sensor and a second sensor signal representing the force of the magnetic field at a sensor position of the second sensor; and
evaluating the first sensor signal and the second sensor signal to determine a quality of the magnet block.

36. The method of claim 35, wherein the step of evaluating the first sensor signal and the second sensor signal, the first sensor signal and the second sensor signal are combined to generate a result signal representing the quality of the magnet block.

37. The method of claim 36, wherein the step of evaluating the first sensor signal and the second sensor signal includes comparing the result signal to a predetermined threshold to determine the quality of the magnet block.

38. A computer program product with a program code configured to perform the method according to claim 35, wherein the computer program product is run on a device.

39. The method of claim 35, wherein end faces of the three magnetic conductors are arranged in one plane corresponding to the arrangement of the three pole surfaces.

40. The method of claim 35, wherein the three magnetic conductors are parallel and spaced apart and include a first side magnet conductor, a middle magnet conductor, and a second side magnet conductor.
